(19) United States
(12) Patent Application Publication
(10) Pub. No.: US 2014/0166329 A1
(43) Pub. Date: Jun. 19, 2014

(54) Dry-Type Transformer Arc Resistant Enclosure Having Pressure Relief Structure

(71) Applicant: ABB TECHNOLOGY AG, Zurich (CH)

(72) Inventors: Robert C. Ballard, Wytheville, VA (US); Edgar A. Wimmer, JR., Bland, VA (US)

(73) Assignee: ABB TECHNOLOGY AG, Zurich (CH)

(21) Appl. No.: 13/716,241

(22) Filed: Dec. 17, 2012

(51) Int. Cl. H05K 5/02; F16K 15/00

(52) U.S. Cl. CPC H05K 5/0213; F16K 15/00
USPC 174/50; 137/14

(57) ABSTRACT

An enclosure for a dry-type transformer includes a bottom wall, a plurality of sidewalls coupled to and extending from the bottom wall, and a top wall coupled to the sidewalls so as to be spaced from the bottom wall. The top wall includes an opening therein. The bottom wall, sidewalls and top wall define an enclosed space for housing a dry-type transformer. Pressure relief structure is associated with the top wall and has at least one flap constructed and arranged in a closed position, to cover the opening. In the event an arc flash occurs in the enclosure creating gas pressure in the enclosure, the flap is constructed and arranged to move from the closed position to an opened position due to the gas pressure acting thereon, permitting the gas pressure to escape from the top of the enclosure through the opening.

### FIELD

The invention relates to dry type transformers and, more particularly, to an arc resistant enclosure of a transformer that has pressure relief structure to allow the escape of hot gasses from the enclosure in a safe manner, in the event of an arc flash.

### BACKGROUND

Dry-type distribution and small power transformers are known in the art, and include a familiar core and winding configuration. It is common to house dry-type distribution transformers in metal enclosures for the purposes of protecting the components from the environment and limiting exposure of people to the equipment. Arc flash events can occur in such electrical equipment during normal operation, system transients, or during maintenance. When an electric arc occurs within the enclosure, it results in a pronounced increase in the pressure and temperature of gas within the enclosure. This sudden increase in gas pressure and temperature poses a risk of hot gas escaping the enclosure in an uncontrolled manner, which in turn poses a severe risk to people in the vicinity.

Thus, there is a need to provide pressure relief structure on a transformer enclosure to permit controlled release of hot gasses from the enclosure in the event of an arc flash.

### SUMMARY

An object of the invention is to fulfill the need referred to above. In accordance with the principles of the present invention, this objective is obtained by providing an enclosure for a dry-type transformer including a bottom wall, a plurality of sidewalls coupled to and extending from the bottom wall, and a top wall coupled to the sidewalls so as to be spaced from the bottom wall. The top wall includes surfaces defining an opening therein. The bottom wall, sidewalls and top wall define an enclosed space constructed and arranged to house a dry-type transformer. Pressure relief structure is associated with the top wall and has at least one flap constructed and arranged in a closed position, to cover the opening. In the event an arc flash occurs in the enclosure creating gas pressure in the enclosure, the flap is constructed and arranged to move from the closed position to an opened position due to the gas pressure acting thereon, permitting the gas pressure to escape from the top of the enclosure through the opening.

In accordance with another aspect of the disclosed embodiment, a method is provided for releasing gas from an enclosure of a dry-type transformer in the event of an arc flash. The method provides an enclosure having walls defining an enclosed space, with a top wall having an opening therein. The opening is covered with a flap in a closed position. In the event an arc flash occurs in the enclosure creating gas pressure in the enclosure, the flap is permitted to move from the closed position to an opened position due to the gas pressure acting thereon, permitting the gas pressure to escape from the top of the enclosure through the opening.

Other objects, features and characteristics of the present invention, as well as the methods of operation and the functions of the related elements of the structure, the combination of parts and economics of manufacture will become more apparent upon consideration of the following detailed description and appended claims with reference to the accompanying drawings, all of which form a part of this specification.

### BRIEF DESCRIPTION OF THE DRAWINGS

The invention will be better understood from the following detailed description of the preferred embodiments thereof, taken in conjunction with the accompanying drawings, wherein like reference numerals refer to like parts, in which:

FIG. 1 is a perspective view of a transformer provided in an enclosure having pressure relief structure in accordance with an embodiment of the invention.

FIG. 2 is a view of a top portion of the transformer enclosure of FIG. 1 shown with pressure relief structure coupled thereto and with a flap thereof in a closed position.

FIG. 3 is a view of the top portion of the transformer of FIG. 1, shown with pressure relief structure coupled thereto and with a flap thereof in an opened position.

FIG. 4 is side view of the pressure relief structure of FIG. 1 shown with a flap in a closed position.

FIG. 5 is an enlarged view of the encircled at 5 in FIG. 4.

FIG. 6 is an enlarged view showing the hinge and the flap in the opened position.

### DETAILED DESCRIPTION OF AN EXEMPLARY EMBODIMENT

The enclosures and principles disclosed in this application are applicable to dry-type transformers of various sizes and ratings. Non-limiting examples of suitable dry-type transformers for use herein include power or distribution dry transformers with power ratings from 112.5 kVA to 25 MVA. Non-limiting examples of suitable commercially available dry transformers include vacuum cast coil, RESIBLOC® and open wound transformers offered by ABB, Inc.

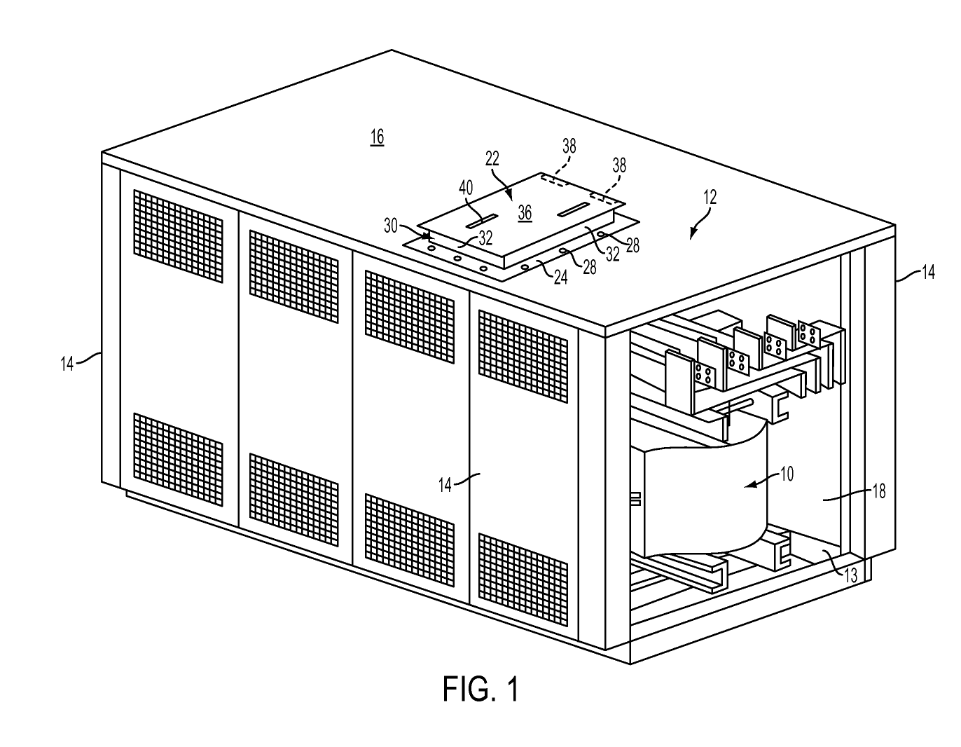

FIG. 1 shows a three-phase dry-type distribution transformer, generally indicated at 10, housed in enclosure, generally indicated at 12. For ease of reference, dry-type transformers will be referenced hereinafter simply as transformers. The enclosure 12 includes a bottom wall 13, a plurality of side walls 14 coupled to and extending from the bottom wall, and a top wall 16 coupled to the sidewalls 14 so as to be spaced from the bottom wall 13 thereby defining an enclosed space 18. In FIG. 1, a right sidewall is shown removed so that the enclosed space 18 can be seen. The bottom wall 14 is constructed and arranged to support the transformer 10 within the space 18. In the embodiment, the sidewalls 14 are preferably substantially perpendicular to the bottom and top walls 13, 18, respectively, to define a generally rectangular box-like structure. Although a rectangular enclosure is shown, it will be understood that the enclosure walls may form any of a number of geometric shapes, such polygonal, i.e., triangle, square, pentagon, etc., or can be circular, oval, elliptical, and the like. Moreover, any number of walls may be employed.

The enclosure 12 is fabricated using generally any material that is capable of providing the functional requirements of the user, including arc fault resistance. The enclosure 12 can be fabricated using heavy gauge sheet steel, aluminum or stainless steel. The enclosure 12 may comply with National Electrical Manufacturers Association (NEMA) 250 Standards.

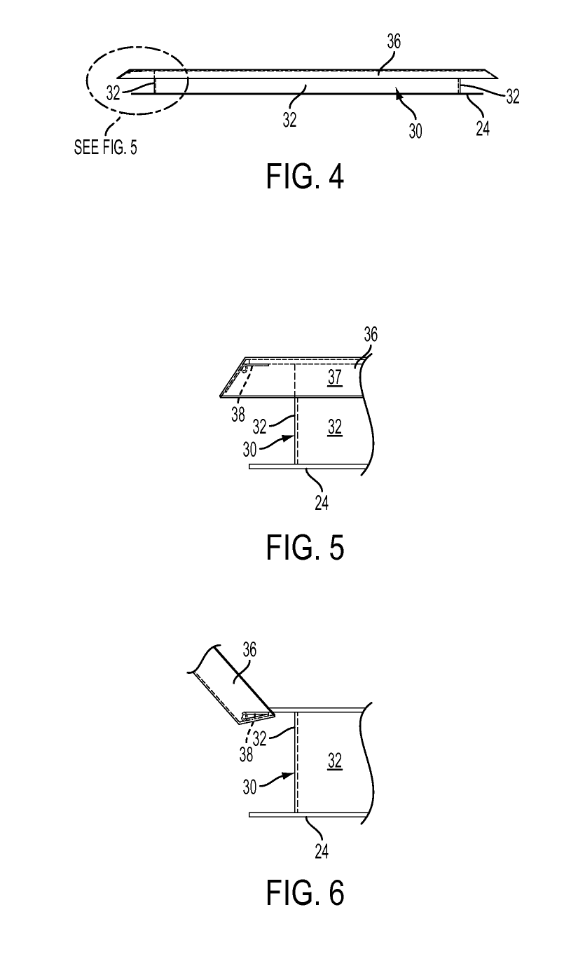

The top wall 16 may comprise one or more generally flat, rigid panels. The top wall 16 includes surfaces defining an opening 20 (FIG. 3) therein. With reference to FIGS. 1-4 and in accordance with an embodiment, pressure relief structure, generally indicated at 22, is coupled to the top wall 16. As best seen in FIG. 3, the pressure relief structure 22 includes a base 24 having surfaces defining an opening 26 that communicates with the opening 20 in the enclosure 12. The base is coupled to the top wall 16 of the enclosure 12 by fasteners 28 or the like.

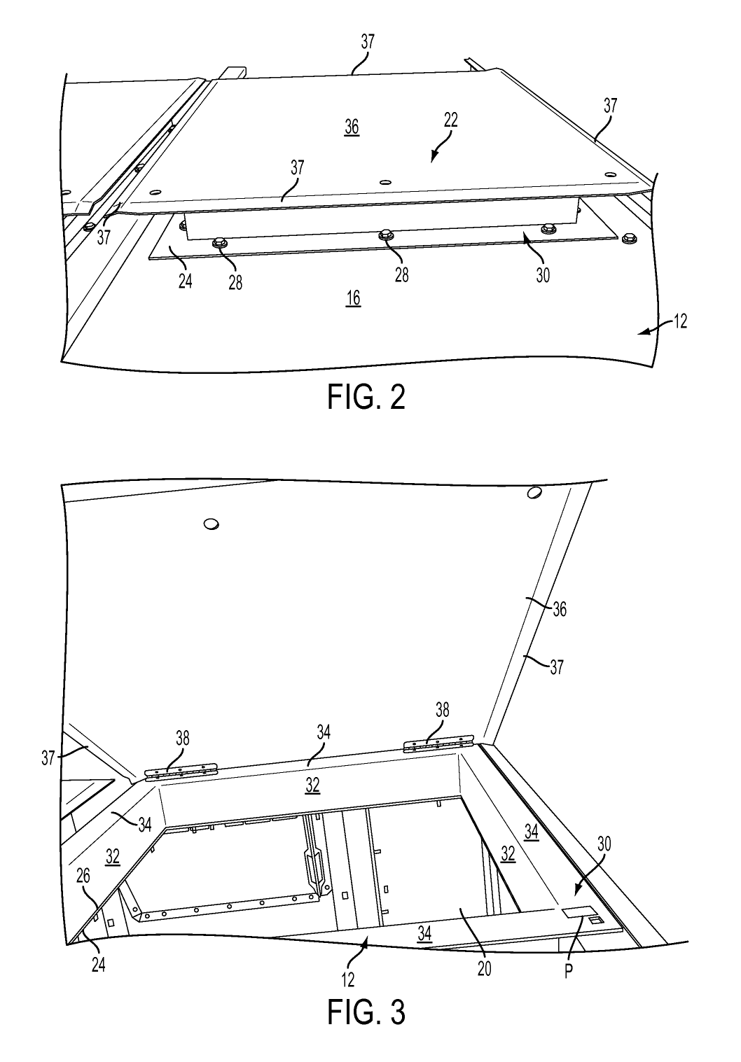

A throat structure, generally indicated at 30, extends from the base 24. The base 24 can be considered to be part of the throat structure 30. The throat structure 30 also includes a plurality of sidewalls 32 coupled to and extending from the base 24 to define an open, box-like structure. The throat structure 30 also includes flange surfaces 34 coupled to and extending transversely from the sidewalls 32. The flange surfaces 34 are planar and are disposed on a common plane P so as to define a resting surface for receiving a flap 36 of the pressure relief structure 22 in a closed position thereof. As shown FIGS. 2 and 3, the flap 36 is substantially planar and preferably overhangs the flange surfaces 34. The flap 36 includes downwardly tapering drip edges 37 on all four edges that reduce the chances of dripping water or foreign particles from entering the enclosure 12.

As shown in FIG. 3, the flap 36 is coupled to the throat structure 30 by at least one hinge connection 38. In the embodiment, two hinge connections are disposed near edges of the flap 36. As shown in FIGS. 2 and 5, the flap 36 is in a closed position, covering the opening 26 in the throat structure 30 and the opening 20 in the enclosure 12 under normal operating conditions of the transformer 10. In the event an arc flash occurs in the enclosure 12 creating gas pressure in the enclosure 12, the flap 36 is constructed and arranged to move about the hinge connection 38 from the closed position to an opened position (FIGS. 3 and 6) due to the gas pressure acting thereon, permitting the gas pressure to escape from the top of the enclosure 12 through the openings 26 and 20. Thus, the hot gasses and any smoke are released into an area above the enclosure 12 that is not typically occupied by personnel. Thus, the personnel in the area can safely evacuate the room(s) containing the equipment with the arc fault.

The flap 36 is preferably a sheet of metal (e.g., steel) and the weight thereof keeps it in the closed position unless a force (arc flash gas pressure) greater than the weight is exerted on the flap 36. To enhance cooling of the dry-type transformer 10, the flap 36 can include at least one cooling vent 40 therein of a configuration that ensures that in the event of an arc flash, the flap 36 will open. The vent 40 is also constructed and arranged so that in the closed position of the flap 36, water cannot easily pass through the vent 40.

The foregoing preferred embodiments have been shown and described for the purposes of illustrating the structural and functional principles of the present invention, as well as illustrating the methods of employing the preferred embodiments and are subject to change without departing from such principles. Therefore, this invention includes all modifications encompassed within the spirit of the following claims.

What is claimed is:

1. An enclosure for a dry-type transformer comprising:
a bottom wall,
a plurality of sidewalls coupled to and extending from the bottom wall,
a top wall coupled to the sidewalls so as to be spaced from the bottom wall, the top wall including surfaces defining an opening therein, the bottom wall, sidewalls and top wall defining an enclosed space constructed and arranged to house a dry-type transformer, and
pressure relief structure associated with the top wall and having at least one flap constructed and arranged in a closed position, to cover the opening and, in the event an arc flash occurs in the enclosure creating gas pressure in the enclosure, the flap is constructed and arranged to move from the closed position to an opened position due to the gas pressure acting thereon, permitting the gas pressure to escape from the top of the enclosure through the opening.

2. The enclosure of claim 1, wherein the flap is movable between the closed and opened positions by at least one hinge connection.

3. The enclosure of claim 1, wherein in the closed position, the flap is constructed and arranged to prevent water from entering the opening.

4. The enclosure of claim 1, wherein the pressure relief structure further comprises:
throat structure mounted on the top wall and having surfaces defining an opening that communicates with the opening in the top wall, the flap being constructed and arranged to cover the opening in the throat structure and the opening in the top wall in the closed position thereof, the flap being connected to the throat structure by at least one hinge connection.

5. The enclosure of claim 4, wherein the throat structure comprises:
a base coupled to the top wall and having surfaces defining the opening in the throat structure,
sidewalls coupled to and extending from the base, and
flange surfaces coupled to and extending transversely from the sidewalls, the flange surfaces being planar and disposed on a common plane so as to define a resting surface for receiving the flap in the closed position thereof.

6. The enclosure of claim 5, wherein the flap is a substantially planar sheet of metal.

7. The enclosure of claim 6, wherein the flap includes downwardly tapering drip edges on each edge thereof.

8. The enclosure of claim 1, wherein the flap has at least one vent therein.

9. A method of releasing gas from an enclosure of a dry-type transformer in the event of an arch flash, the method comprising the steps of:
providing an enclosure having walls defining an enclosed space, with a top wall having an opening therein,
covering the opening with a flap in a closed position, and
in the event an arc flash occurs in the enclosure creating gas pressure in the enclosure, permitting the flap to move from the closed position to an opened position due to the gas pressure acting thereon, permitting the gas pressure to escape from the top of the enclosure through the opening.

10. The method of claim 9, wherein the step of permitting the flap to move includes the use of a hinge connection.

11. The method of claim 9, wherein the covering step includes:
mounting throat structure on the top wall, the throat structure having surfaces defining an opening that communicates with the opening in the top wall, the flap covering the opening in the throat structure and the opening in the top wall in the closed position thereof, and
connecting the flap to the throat structure by at least one hinge connection.

12. The method of claim 11, wherein the throat structure comprises:
a base coupled to the top wall and having surfaces defining the opening in the throat structure,
sidewalls coupled to and extending from the base, and
flange surfaces coupled to and extending transversely from the sidewalls, the flange surfaces being planar and disposed on a common plane, the method further comprising:
permitting the flap to rest on the flange surfaces in the closed position thereof.

13. The method of claim 9, further comprising:
providing downwardly tapering drip edges on each edge of the flap.

14. The method of claim 9, further comprising:
providing at least one vent in the flap.
